(19) United States
(12) Patent Application Publication
(10) Pub. No.: US 2019/0189886 A1
(43) Pub. Date: Jun. 20, 2019

(54) POWER SUPPLYING DEVICE AND HEATING SYSTEM

(71) Applicant: INDUSTRIAL TECHNOLOGY RESEARCH INSTITUTE, Hsinchu (TW)

(72) Inventors: Yion-Ni LIU, Hsinchu City (TW); Hsu-Shen CHU, Hsinchu City (TW); Cheng-Ting HSU, Hsinchu City (TW)

(73) Assignee: INDUSTRIAL TECHNOLOGY RESEARCH INSTITUTE, Hsinchu (TW)

(21) Appl. No.: 15/843,297

(22) Filed: Dec. 15, 2017

(51) Int. Cl. H01L 35/32; H01L 35/10; H05B 3/06

(52) U.S. Cl. CPC H01L 35/32; H05B 3/06; H01L 35/10

(57) ABSTRACT

A power supplying device and a heating system are disclosed. The power supplying device includes a first base, a thermoelectric transmitting module, a conducting circuit, and a second base. The first base has a first flow path and a supporting surface. The thermoelectric transmitting module is disposed on the supporting surface. The conducting circuit is disposed on the supporting surface and electrically connected to the thermoelectric transmitting module. At least one portion of a projection of the first flow path to the supporting surface overlaps the conducting circuit. The second base is stacked on the thermoelectric transmitting module, and the thermoelectric transmitting module is positioned between the first base and the second base. The heating system includes the power supplying device and a heater powered by the power supplying device.

### TECHNICAL FIELD

The disclosure relates to a power supplying device and a heating system, more particularly to a power supplying device which can generate electrical power through thermoelectric conversion and a heating system which is powered by the power supplying device.

### BACKGROUND

In recent years, some materials are discovered that a temperature difference at either end will be produced as it is electrified, and these materials will produce electrical current when the temperature difference exists. Accordingly, these materials have thermoelectric properties and are made into a thermoelectric conversion module in products, such as insulation coasters, mini refrigerators, condensing systems of mini dehumidifiers, for adjusting temperature. Furthermore, the thermoelectric conversion module can generate electrical currents when temperature difference is created, so it is also applicable to thermal recycling to convert thermal energy into electrical energy. While converting thermal energy into electrical energy, the required amount of output voltage and current is obtained through connecting chips of the thermoelectric conversion module in series or in parallel by an electrically conductive circuit.

However, the thermoelectric conversion module is usually disposed in a high-temperature environment. The material of the electrically conductive circuits has lower thermal durability than that of the material of the thermoelectric conversion module, which might result in malfunctioning of the electrically conductive circuit.

### SUMMARY

According to the aforementioned problem, the present disclosure provides a power supplying device and a heating system that are capable of preventing an electrically conductive circuit from overheating.

One embodiment of the disclosure provides a power supplying device including a first base, a thermoelectric conversion module, an electrically conductive circuit and a second base. The first base has a first flow channel and a supporting surface. The thermoelectric conversion module is disposed on the supporting surface. The electrically conductive circuit is disposed on the supporting surface and electrically connected to the thermoelectric conversion module. At least a part of a projection of the first flow channel on the supporting surface overlaps the electrically conductive circuit. The second base is stacked on the thermoelectric conversion module, and the thermoelectric conversion module is located between the first base and the second base.

One embodiment of the disclosure provides a heating system including the aforementioned power supplying device and a heater. The heater is electrically connected to the electrically conductive circuit of the power supplying device.

The aforementioned summary and the following detailed description are set forth in order to provide a thorough understanding of the disclosed embodiment and provide a further explanations of claims of the disclosure.

### BRIEF DESCRIPTION OF THE DRAWINGS

FIG. 1 is an exploded perspective view of a power supplying device in accordance with one embodiment of the disclosure.

FIG. 2 is a top view of the power supplying device of FIG. 1.

FIG. 3 is a cross-sectional view of the power supplying device taken along line III-III of FIG. 2.

FIG. 4 is a cross-sectional view of a power supplying device in accordance with another embodiment of the disclosure.

FIG. 5 is a cross-sectional view of a power supplying device in accordance with another embodiment of the disclosure.

FIG. 6 is a cross-sectional view of a power supplying device in accordance with another embodiment of the disclosure.

FIG. 7 is a cross-sectional view of a power supplying device in accordance with another embodiment of the disclosure.

### DETAILED DESCRIPTION

The detailed features and advantages of the embodiments of the present disclosure are described in the following embodiments, which enables one skilled in the art to understand and implement the technical contents of the embodiments of the present disclosure, and one skilled in the art can easily understand the objects and advantages related to the present disclosure by according to the content disclosed in the specification, claims and the drawings. The following embodiments are further details of the present disclosure, but are not intended to limit the scope of the present disclosure.

The drawings may not be drawn to actual size or scale, some exaggerations may be necessary in order to emphasize basic structural relationships, while some are simplified for clarity of understanding, and the present disclosure is not limited thereto. It is allowed to have various adjustments under the spirit of the present disclosure.

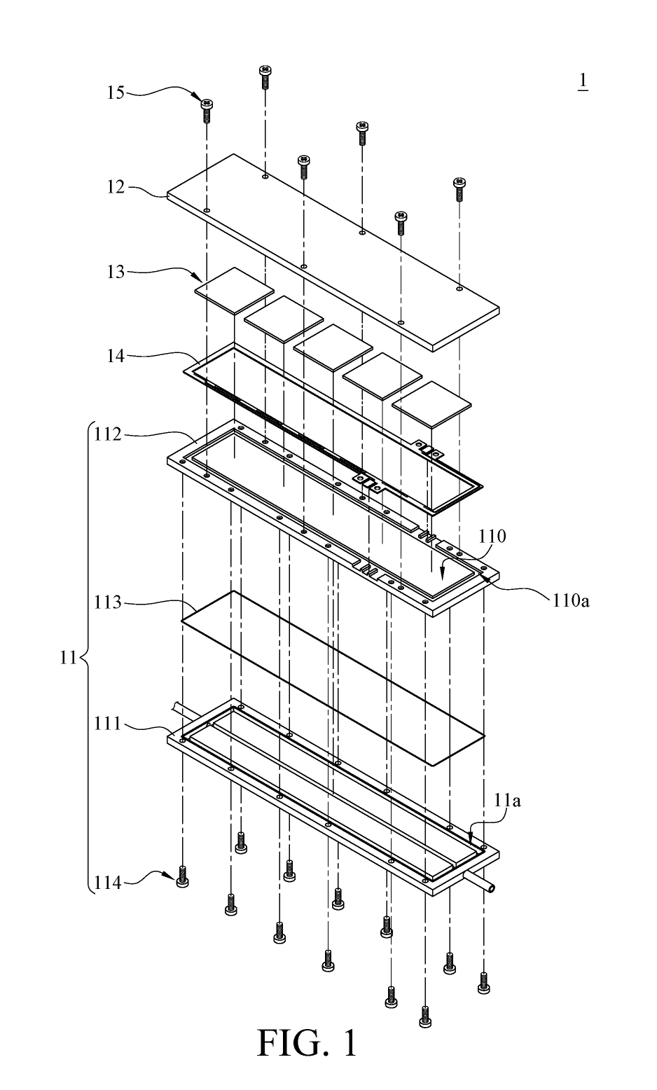

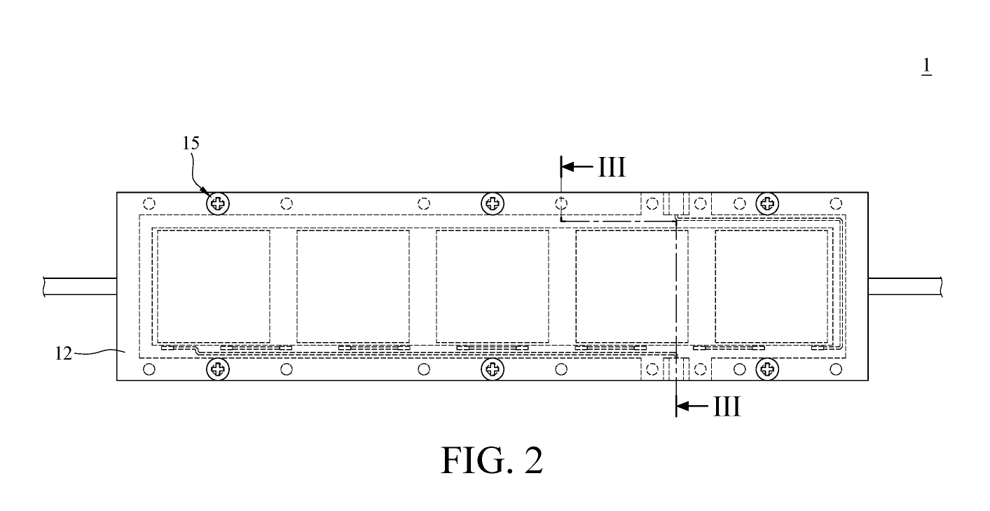

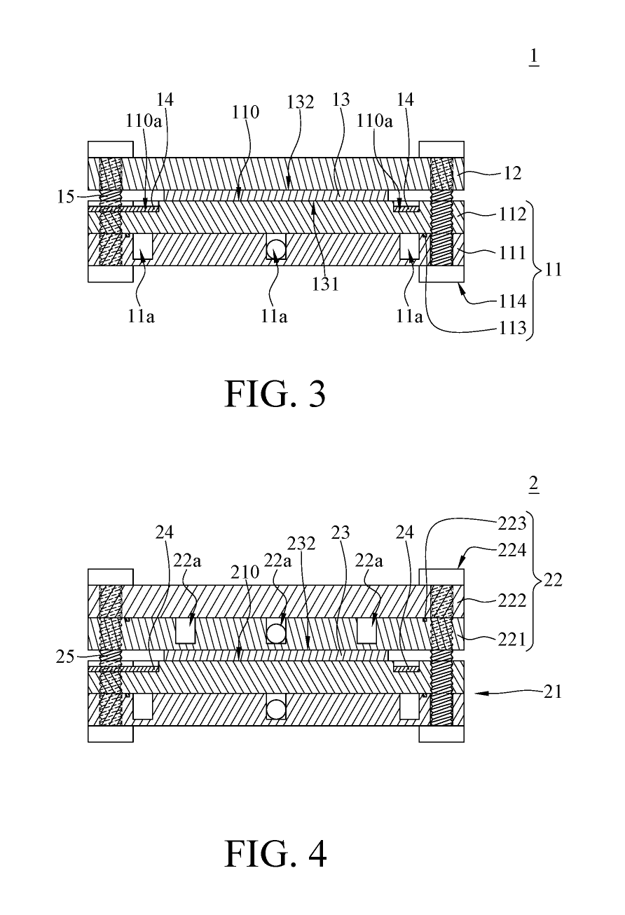

Please refer to FIG. 1, FIG. 2 and FIG. 3. FIG. 1 is an exploded perspective view of a power supplying device 1 in accordance with one embodiment of the disclosure, FIG. 2 is a top view of the power supplying device 1 of FIG. 1, FIG. 3 is a cross-sectional view of the power supplying device taken along line III-III of FIG. 2. In this embodiment, the power supplying device 1 includes a first base 11, a second base 12, a thermoelectric conversion module 13, an electrically conductive circuit 14 and fasteners 15.

The first base 11 has a first flow channel 11a and a supporting surface 110. The first base 11 includes a first bottom plate 111, a first top plate 112, a first leak-proof member 113 and first base fasteners 114. The first bottom plate 111 and the first top plate 112 are stacked on each other and together form the first flow channel 11a. The supporting surface 110 of the first base 11 is on the first top plate 112. The supporting surface 110 of the first top plate 112 has a containing groove 110a. In this embodiment, a part of the containing groove 110a is in a ring shape surrounding the supporting surface 110. At least a part of a projection of the first flow channel 11a on the supporting surface 110 overlaps the containing groove 110a. A material of the first bottom plate 111 and a material of the first top plate 112 may include polyimide, glass fiber, ceramic or metal, but are not restricted. The first flow channel 11a is configured for coolant to flow therethrough.

In this embodiment, a top surface of the first bottom plate 111 has a groove, and the first top plate 112 covers the groove. The first bottom plate 111 and the first top plate 112 together form the first flow channel 11a at the groove. The present disclosure is not limited to how the first flow channel 11a is formed, the first flow channel may be formed through other ways. The first leak-proof member 113 surrounds the first flow channel 11a and is disposed between the first bottom plate 111 and the first top plate 112 in order to prevent coolant from leaking from the first flow channel 11a. The first bottom plate 111 and the first top plate 112 are fixed to each other through the first base fasteners 114.

The thermoelectric conversion module 13 is disposed on the supporting surface 110. In this embodiment, the thermoelectric conversion module 13 includes a plurality of thermoelectric chips. The thermoelectric conversion module 13 has a cooling side surface 131 and a heating side surface 132. The thermoelectric conversion module 13 is disposed on the supporting surface 110 through the cooling side surface 131 in direct contact with the supporting surface 110 of the first top plate 112. Since the thermoelectric conversion module 13 is disposed on the supporting surface 110, and the containing groove 110 is disposed around the periphery of the supporting surface 110, the thermoelectric conversion module 13 is also surrounded by the containing groove 110a. The electrically conductive circuit 14 is disposed on the supporting surface 110 and is embedded in the containing groove 110a. The electrically conductive circuit 14 is electrically connected to the thermoelectric conversion module 13, such that output voltage and output current from the power supplying device 1 are obtained through connecting the thermoelectric chips of the thermoelectric conversion module 13 in series or in parallel. At least a part of the projection of the first flow channel 11a on the supporting surface 110 overlaps the electrically conductive circuit 14, and another part of the projection of the first flow channel 11a on the supporting surface 110 overlaps the thermoelectric conversion module 13. When coolant flows in the first flow channel 11a, the part of the projection of the first flow channel 11a on the supporting surface 110 overlapping the electrically conductive circuit 14 is able to exchange heat with the electrically conductive circuit 14, thereby preventing the electrically conductive circuit 14 from overheating, and the another part of the projection of the first flow channel 11a on the supporting surface 110 overlapping the thermoelectric conversion module 13 is also able to cool the cooling side surface 131 of the thermoelectric conversion module 13. An equivalent resistance of a combination of the thermoelectric conversion module 13 and the electrically conductive circuit 14 may range from 12 ohms to 15 ohms. The electrically conductive circuit 14 may be printed onto a copper clad laminate or a ceramic substrate before being disposed.

The second base 12 is stacked on and covers the thermoelectric conversion module 13, and may be in direct contact with the heating side surface 132 of the thermoelectric conversion module 13. The second base 12 may be not in direct contact with the electrically conductive circuit 14. The thermoelectric conversion module 13 is located between the first base 11 and the second base 12. The first base 11 and the second base 12 are fixed to each other through the fasteners 15. The first base 11 and the second base 12 are not in direct contact with each other in order to decrease heat transferred from the second base 12 to the first base 11. A material of the second base 12 may have higher thermal durability than that of a material of the first base 11. The material of the second base 12 may include, aluminum, copper or alloys thereof.

When the power supplying device 1 is in operation, the second base 12 is positioned near a heat source in order to raise the temperature of the second base 12. Meanwhile, coolant flows through the first flow channel 11a of the first base 11 to cool the first base 11. This can increase a temperature difference between the two opposite surfaces of the thermoelectric conversion module 13, thereby increasing a power supply rate of the thermoelectric conversion module 13.

Furthermore, the power supplying device 1 is able to be applied to a heating system. The heating system may include the power supplying device 1 and a heater. The heater is electrically connected to the electrically conductive circuit 14 of the power supplying device 1 to receive electrical power from the power supplying device 1. The heater may be a heating resistor. A ratio of an equivalent resistance of the heater to an equivalent resistance of the power supplying device 1 ranges from 1 to 2.7. In addition, the equivalent resistance of the power supplying device 1 may equal to the equivalent resistance of the combination of the thermoelectric conversion module 13 and the electrically conductive circuit 14. Therefore, the equivalent resistance of the heater may range from 12 ohms to 40.5 ohms.

The heating system is applicable to incinerators. When combusting objects in the incinerators, a combustion-supporting gas is usually provided for completely combusting objects. The combustion-supporting gas is, for example, oxygen or oxygen-containing gas. The state of the objects to be combusted in the incinerators is not restricted, and the objects may be in solid form, liquid form or gaseous form. A gas provided into the incinerator through an inlet thereof may include the combustion-supporting gas or the objects to be combusted. During the combustion, if a temperature of the gas being provided into the inlet is too low, a combustion reaction rate may be decreased, and it may lead to incomplete combustion. As such, a user can dispose the power supplying device 1 on the incinerator with the second base 12 facing a heat source of the incinerator and the heater disposed in the inlet of the incinerator. The power supplying device 1 is able to draw heat energy generated by the incinerator and convert it into electrical energy for the heater to generate heat energy to heat the gas in the inlet, thereby increasing the combustion reaction rate of the incinerator.

In one exemplary embodiment of the disclosure, the equivalent resistance of the heater is approximately 15 ohms, and the equivalent resistance of the power supplying device 1 is approximately 12.05 ohms in a room temperature around 20° C. The second base 12 of the power supplying device 1 is disposed in an environment having a temperature approximately 220° C., such that a temperature of the heating side surface 132 of the thermoelectric conversion module 13 is also approximately 220° C. When a temperature difference between the heating side surface 132 of the thermoelectric conversion module 13 and the cooling side surface 131 of the thermoelectric conversion module 13 is approximately or higher than 150° C., meaning a temperature of the cooling side surface 131 of the thermoelectric conversion module 13 is approximately or lower than 70° C., then the electrical power generated by the power supplying device 1 is able to drive the heater to a temperature higher than 60° C., enabling the gas in the inlet of the incinerator to be heated to a temperature higher than 50° C. Therefore, a combustion efficiency of the incinerator is improved because of the heated gas in the inlet of the incinerator.

In another exemplary embodiment of the disclosure that the equivalent resistance of the heater is around 26.8 ohms, and other conditions are similar to the aforementioned case. When the temperature difference between the heating side surface 132 of the thermoelectric conversion module 13 and the cooling side surface 131 of the thermoelectric conversion module 13 is approximately or higher than 150° C., the electrical power generated by the power supplying device 1 is able to drive the heater to a temperature higher than 60° C. so as to heat the gas in the inlet of the incinerator, thereby improving the combustion efficiency of the incinerator.

Please refer to FIG. 4, which is a cross-sectional view of a power supplying device 2 in accordance with another embodiment of the disclosure. In this embodiment, the power supplying device 2 includes a first base 21, a second base 22, a thermoelectric conversion module 23, an electrically conductive circuit 24 and fasteners 25. Except that the second base 22 has a second flow channel 22a, the other components are similar to or the same as that of the power supplying device 1 in FIG. 3.

The second base 22 includes a second bottom plate 221, a second top plate 222, a second leak-proof member 223 and second base fasteners 224. The second top plate 222 and the second bottom plate 221 are stacked on each other and together form the second flow channel 22a. The second bottom plate 221 is stacked on and covers the thermoelectric conversion module 23. At least a part of a projection of the second flow channel 22a on a supporting surface 210 overlaps the thermoelectric conversion module 23. The second flow channel 22a is configured for heating fluid to flow therethrough in order to heat a heating side surface 232 of the thermoelectric conversion module 23.

In this embodiment, a top surface of the second bottom plate 221 has a groove, and the second top plate 222 covers the groove. The second bottom plate 221 and the second top plate 222 together form the second flow channel 22a at the groove. The present disclosure is not limited to how the second flow channel 22a is formed, the second flow channel may be formed through other ways. The second leak-proof member 223 surrounds a periphery of the second flow channel 22a and is pressed by and disposed between the second bottom plate 221 and the second top plate 222 in order to prevent fluid from leaking from the second flow channel 22a. The second bottom plate 221 and the second top plate 222 are fixed to each other through the second base fasteners 224.

The power supplying device 2 is also able to be applied to a heating system. When the power supplying device 2 is in operation, the second base 22 does not need to be positioned close to a heat source. The heating fluid can be heated by the heat source, and then the heating fluid is channeled into the second flow channel 22a to heat the heating side surface 232 of the thermoelectric conversion module 23.

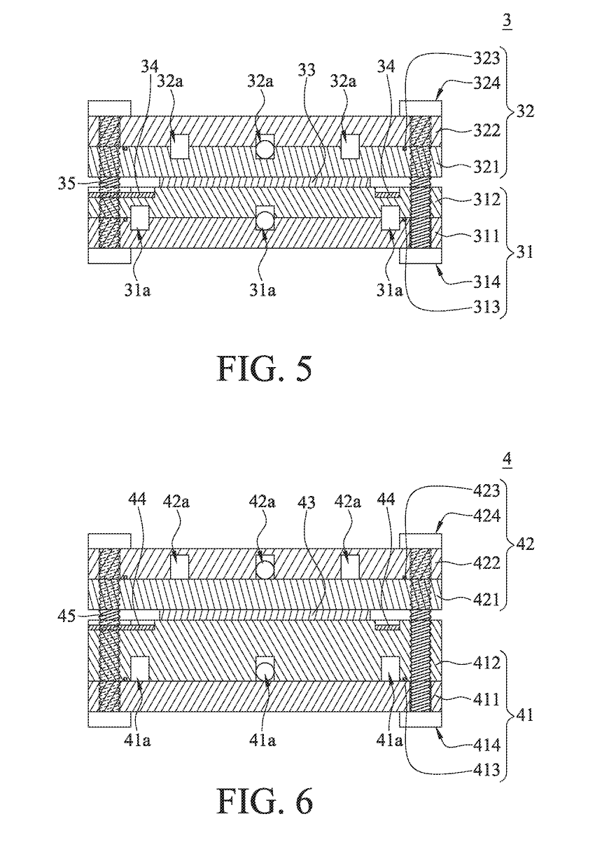

Please refer to FIG. 5, which is a cross-sectional view of a power supplying device 3 in accordance with another embodiment of the disclosure. In this embodiment, the power supplying device 3 includes a first base 31, a second base 32, a thermoelectric conversion module 33, an electrically conductive circuit 34 and fasteners 35. Except how a first flow channel 31a of the first base 31 and a second flow channel 32a of the second base 32 are formed, the other components are similar to or the same as that of the power supplying device 2 in FIG. 4.

In this embodiment, a top surface of a first bottom plate 311 and a bottom surface of a first top plate 312 have a groove, respectively, and when the first top plate 312 covers the first bottom plate 311, these grooves are aligned with each other to form the first flow channel 31a. The present disclosure is not limited to how the first flow channel 31a is formed, the first flow channel may be formed through other ways. A first leak-proof member 313 is pressed by and disposed between the first bottom plate 311 and the first top plate 312 and surrounds a periphery of the first flow channel 31a. The first bottom plate 311 and the first top plate 312 are fixed to each other through first base fasteners 314.

Furthermore, a top surface of a second bottom plate 321 and a bottom surface of a second top plate 322 both have a groove, and when the second top plate 322 covers the second bottom plate 321, these grooves are aligned with each other to form the second flow channel 32a. The present disclosure is not limited to how the second flow channel 32a is formed, the second flow channel may be formed through other ways. A second leak-proof member 323 is pressed by and disposed between the second bottom plate 321 and the second top plate 322 and surrounds a periphery of the second flow channel 32a. The second bottom plate 321 and the second top plate 322 are fixed to each other through second base fasteners 324.

The power supplying device 3 is also applicable to a heating system.

Please refer to FIG. 6, which is a cross-sectional view of a power supplying device 4 in accordance with another embodiment of the disclosure. In this embodiment, the power supplying device 4 includes a first base 41, a second base 42, a thermoelectric conversion module 43, an electrically conductive circuit 44 and fasteners 45. Except how a first flow channel 41a of the first base 41 and a second flow channel 42a of the second base 42 are formed, the other components are similar to or the same as that of the power supplying device 2 in FIG. 4.

In this embodiment, a bottom surface of a first top plate 412 has a groove, and when the first top plate 412 covers a first bottom plate 411, the first bottom plate 411 and the first top plate 412 together form the first flow channel 41a at the groove. The present disclosure is not limited to how the first flow channel 41a is formed, the first flow channel may be formed through other ways. A first leak-proof member 413 is pressed by and disposed between the first bottom plate 411 and the first top plate 412 and surrounds the first flow channel 41a. The first bottom plate 411 and the first top plate 412 are fixed to each other through first base fasteners 414.

Furthermore, a bottom surface of a second top plate 422 has a groove, and when the second top plate 422 covers a second bottom plate 421, the second bottom plate 421 and the second top plate 422 together form the second flow channel 42a at the groove. The present disclosure is not limited to how the second flow channel 42a is formed, the second flow channel may be formed through other ways. A second leak-proof member 423 is pressed by and disposed between the second bottom plate 421 and the second top plate 422 and surrounds a periphery of the second flow channel 42a. The second bottom plate 421 and the second top plate 422 are fixed to each other through second base fasteners 424.

The power supplying device 4 is also applicable to a heating system.

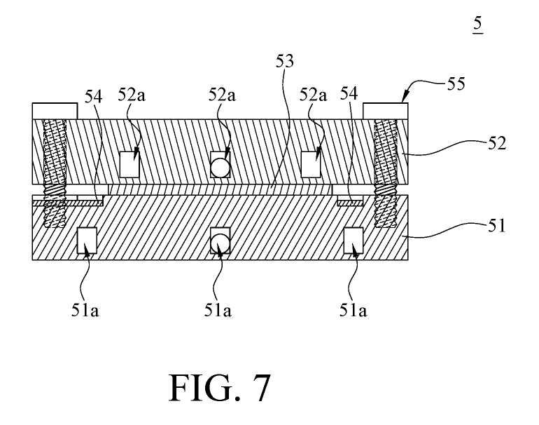

Please refer to FIG. 7, which is a cross-sectional view of a power supplying device 5 in accordance with another embodiment of the disclosure. In this embodiment, the power supplying device 5 includes a first base 51, a second base 52, a thermoelectric conversion module 53, an electrically conductive circuit 54 and fasteners 55. Except how a first flow channel 51a of the first base 51 and a second flow channel 52a of the second base 52 are formed, the other components are similar to or the same as that of the power supplying device 2 in FIG. 4.

In this embodiment, the first base 51 is an inseparable object formed by molding or welding, and the first flow channel 51a is formed in the first base 51 at the time when the first base 51 is formed. The present disclosure is not limited to how the first flow channel 51a is formed, the first flow channel may be formed through other ways. The second base 52 is also an inseparable object formed by molding or welding, and the second flow channel 52a is formed in the second base 52 at the time when the second base 52 is formed. The present disclosure is not limited to how the second flow channel 52a is formed, the second flow channel may be formed through other ways.

The power supplying device 5 is also applicable to a heating system.

Furthermore, the disclosure is not restricted to the combination of the aforementioned first bases 11, 21, 31, 41, 51 and the second bases 12, 22, 32, 42, 52, any one of the first bases is able to be adapted to any one of the second bases.

Accordingly, in the power supplying device and the heating system in one embodiment of the present disclosure, the part of the projection of the first flow channel on the supporting surface overlapping the electrically conductive circuit cools the electrically conductive circuit by coolant flowing through the first flow channel, thereby preventing the electrically conductive circuit from overheating. Furthermore, electrical power generated by the power supplying device can be used to drive the heater of the heating system, such that the heater is able to heat the gas in the inlet of the incinerator, thereby increasing the combustion reaction rate of the incinerator.

The disclosure is described by the foregoing embodiments, but these embodiments are not intended to limit the disclosure. Changes and modifications without departing from the spirit of the present disclosure all fall within the scope of the present disclosure. The scope of the disclosure is defined by the following claims and their equivalents.

### SYMBOL DESCRIPTION

| | |
|---|---|
| 1 [symbol] 2 [symbol] 3 [symbol] 4 [symbol] 5 | power supplying device |
| 11 [symbol] 21 [symbol] 31 [symbol] 41 [symbol] 51 | first base |
| 11a [symbol] 31a [symbol] 41a [symbol] 51a | first flow channel |
| 110 [symbol] 210 | supporting surface |
| 110a | containing groove |
| 111 [symbol] 311 [symbol] 411 | first bottom plate |
| 112 [symbol] 312 [symbol] 412 | first top plate |
| 113 [symbol] 313 [symbol] 413 | first leak-proof member |
| 114 [symbol] 314 [symbol] 414 | first base fastener |
| 12 [symbol] 22 [symbol] 32 [symbol] 42 [symbol] 52 | second base |
| 13 [symbol] 23 [symbol] 33 [symbol] 43 [symbol] 53 | thermoelectric conversion module |
| 131 | cooling side surface |
| 132 [symbol] 232 | heating side surface |
| 14 [symbol] 24 [symbol] 34 [symbol] 44 [symbol] 54 | electrically conductive circuit |
| 15 [symbol] 25 [symbol] 35 [symbol] 45 [symbol] 55 | fastener |
| 22a [symbol] 32a [symbol] 42a [symbol] 52a | second flow channel |
| 221 [symbol] 321 [symbol] 421 | second bottom plate |
| 222 [symbol] 322 [symbol] 422 | second top plate |
| 223 [symbol] 323 [symbol] 423 | second leak-proof member |
| 224 [symbol] 324 [symbol] 424 | second base fastener |

1. A power supplying device, comprising:
a first base, having a first flow channel and a supporting surface;
a thermoelectric conversion module, disposed on the supporting surface;
an electrically conductive circuit, disposed on the supporting surface and electrically connected to the thermoelectric conversion module, and at least a part of a projection of the first flow channel on the supporting surface overlapping the electrically conductive circuit; and
a second base, stacked on and covering the thermoelectric conversion module, and the thermoelectric conversion module being located between the first base and the second base;
wherein the electrically conductive circuit surrounds a periphery of the thermoelectric conversion module.

2. The power supplying device according to claim 1, wherein the first base has a containing groove on the supporting surface, and the electrically conductive circuit is embedded in the containing groove.

3. The power supplying device according to claim 1, wherein the thermoelectric conversion module has a cooling side surface and a heating side surface, the cooling side surface is in contact with the supporting surface of the first base, and the second base is in contact with the heating side surface.

4. The power supplying device according to claim 1, wherein at least another part of the projection of the first flow channel on the supporting surface overlaps the thermoelectric conversion module.

5. The power supplying device according to claim 1, wherein the first base comprises a first bottom plate, a first top plate and a first leak-proof member, the first top plate and the first bottom plate are stacked on each other and together form the first flow channel, the supporting surface is on the first top plate, and the first leak-proof member is pressed by and disposed between the first bottom plate and the first top plate and surrounds a periphery of the first flow channel.

6. The power supplying device according to claim 1, wherein the second base has a second flow channel, and at least a part of a projection of the second flow channel on the supporting surface overlaps the thermoelectric conversion module.

7. The power supplying device according to claim 6, wherein the second base comprises a second bottom plate, a second top plate and a second leak-proof member, the second top plate and the second bottom plate are stacked on each other and together form the second flow channel, the second bottom plate is stacked on and covers the thermoelectric conversion module, and the second leak-proof member is pressed by and disposed between the second bottom plate and the second top plate and surrounds a periphery of the second flow channel.

8. The power supplying device according to claim 1, further comprising a fastener, the first base and the second base being fixed to each other through the fastener.

9. The power supplying device according to claim 1, wherein a material of the first base comprises polyimide, glass fiber, ceramic or metal, and a material of the second base comprises aluminum, copper or alloys thereof.

10. The power supplying device according to claim 1, wherein the electrically conductive circuit is printed onto a copper clad laminate or a ceramic substrate.

11. The power supplying device according to claim 1, wherein an equivalent resistance of a combination of the thermoelectric conversion module and the electrically conductive circuit ranges from 12 ohms to 15 ohms.

12. A heating system, comprising:
the power supplying device according to claim 1; and
a heater, electrically connected to the electrically conductive circuit of the power supplying device.

13. The heating system according to claim 12, wherein a ratio of an equivalent resistance of the heater to an equivalent resistance of the power supplying device ranges from 1 to 2.7.

14. The heating system according to claim 12, wherein the first base has a containing groove on the supporting surface, and the electrically conductive circuit is embedded in the containing groove.

15. The heating system according to claim 12, wherein the thermoelectric conversion module has a cooling side surface and a heating side surface, the cooling side surface is in contact with the supporting surface of the first base, and the second base is in contact with the heating side surface.

16. The heating system according to claim 12, wherein at least another part of the projection of the first flow channel on the supporting surface overlaps the thermoelectric conversion module.

17. The heating system according to claim 12, wherein the first base comprises a first bottom plate, a first top plate and a first leak-proof member, the first top plate and the first bottom plate are stacked on each other and together form the first flow channel, the supporting surface is on the first top plate, and the first leak-proof member is pressed by and disposed between the first bottom plate and the first top plate and surrounds a periphery of the first flow channel.

18. The heating system according to claim 12, wherein the second base has a second flow channel, and at least a part of a projection of the second flow channel on the supporting surface overlaps the thermoelectric conversion module.

19. The heating system according to claim 18, wherein the second base comprises a second bottom plate, a second top plate and a second leak-proof member, the second top plate and the second bottom plate are stacked on each other and together form the second flow channel, the second bottom plate is stacked on and covers the thermoelectric conversion module, and the second leak-proof member is pressed by and disposed between the second bottom plate and the second top plate and surrounds a periphery of the second flow channel.

20. The heating system according to claim 12, wherein the power supplying device further comprises a fastener, the first base and the second base are fixed to each other through the fastener.

21. The heating system according to claim 12, wherein a material of the first base comprises polyimide, glass fiber, ceramic or metal, and a material of the second base comprises aluminum, copper or alloys thereof.

22. The heating system according to claim 12, wherein the electrically conductive circuit is printed onto a copper clad laminate or a ceramic substrate.

23. The heating system according to claim 12, wherein an equivalent resistance of a combination of the thermoelectric conversion module and the electrically conductive circuit ranges from 12 ohms to 15 ohms.
